(19) United States
(12) Patent Application Publication
(10) Pub. No.: US 2009/0146222 A1
(43) Pub. Date: Jun. 11, 2009

(54) METHOD FOR FABRICATION OF SINGLE ELECTRON TRANSISTORS

(75) Inventor: Naveen AGRAWAL, Singapore (SG)

Correspondence Address: ROTHWELL, FIGG, ERNST & MANBECK, P.C., 1425 K STREET, N.W., SUITE 800, WASHINGTON, DC, 20005, US

(73) Assignee: SYSTEMS ON SILICON MANUFACTURING CO. PTE. LTD., Singapore (SG)

(21) Appl. No.: 11/951,785

(22) Filed: Dec. 6, 2007

(51) Int. Cl. H01L 21/8234; H01L 27/088

(52) U.S. Cl. 257/401; 438/275; 257/E27.06; 257/E21.616

(57) ABSTRACT

A method for fabricating a Single Electron Transistor (SET). The method comprises forming a FinFET structure, forming an SET structure from the FinFET structure such that an active area of the SET structure is formed from a channel of the FinFET structure, whereby the active area is self-aligned with a source and a drain of the FinFET structure to form the SET structure.

### FIELD OF INVENTION

The present invention relates broadly to a method for fabricating a Single Electron Transistor (SET), and to SET(s) fabricated using the method.

### BACKGROUND

Transistors are the building blocks of many modern electronic devices. They are the small switches that perform millions of on and off operations every second in these devices, examples of which include memory chips and microprocessors. The three main components of a transistor are the source, the drain and the gate. A common type of transistor is the Field Effect Transistor (FET). Examples of FET include metal-oxide-semiconductor FET (MOSFET), junction FET (JFET) and metal-semiconductor FET (MESFET). Each FET can have one, or multiple gates that control the current flow in the channel between the source and the drain.

In double gate FET, the two gates may be positioned vertically with reference to the wafer plane, separated by the gate oxide layers and the bulk silicon wafer. Alternatively, the gates may be positioned in-plane with the wafer and the silicon around which the gates are formed could be in the form of a thin strip connecting the source and the drain. This type of FET is called double gate FinFET. The manufacturing techniques of double gate FinFET are well understood and may involve multiple material deposition and removal processes.

As electronic devices continue to shrink in size and pack more applications, the integrated circuits (IC) or chips inside the devices need to have a smaller physical footprint, allow a greater drive current and possess more processing power. One solution is to have greater transistor density per unit wafer area by reducing the component dimensions such as the gate size. The current fabrication methods and device architecture are starting to face the physical limitations to scale much smaller; hence, it is not viable to keep reducing the gate size. Alternatively, a fundamentally different type of transistor should be used, such as the Single Electron Transistor (SET).

The physics of SET are understood in the art and will not be discussed in detail herein. Due to its unique mechanism, SET can operate on a smaller voltage and thus consumes much less power than existing FETs. However, as the tunneling of electrons from the source to the drain occurs on a quantum level, the silicon island, which is positioned at the center of the active area between the source and the drain, needs to be very small for the SET to work. The dimensions of the islands may be from a few nanometers to a few tens of nanometers, while the gaps between the islands and respective sources and drains may be less than ten nanometers. The challenges are to fabricate multitudes of silicon islands with better size uniformity and small enough for the SET to work optimally, and precisely separate and align them with respective sources and drains, in a cost-effective way, for a production worthy process.

Currently, one SET fabrication method involves the use of localized silicon oxidation in which areas other than the sources, the drains and the islands are oxidized through an oxidation process such as thermal oxidation, or localized laser burning and the remaining silicon material forms the SET structures. The problem with this method is that it is difficult to control both the dimensions of the silicon islands and their alignment with respective sources and drains.

Another SET fabrication method makes use of electron beam (E-beam) lithography. In this method, an E-beam is used to trace areas to be masked with a reagent. The exposed areas then undergo an etching process to remove unwanted silicon material. The remaining silicon material forms the SET structure. However, as the E-beam is traced linearly, this process may be very slow and therefore economically not viable on a production scale. In addition, the E-beam process may not be able to produce precise alignment of the islands with respective sources and drains.

A need therefore exists to provide method for the fabrication of SET that seeks to address at least one of the above problems.

### SUMMARY

In accordance with a first aspect of the present invention, there is provided a method for fabricating a Single Electron Transistor (SET), the method comprising forming a FinFET structure, and forming an SET structure from the FinFET structure such that an active area of the SET structure is formed from a channel of the FinFET structure, whereby the active area is self-aligned with a source and a drain of the FinFET structure to form the SET structure.

The said method may further comprise forming an insulator layer around the active area.

The forming of the insulator layer may comprise a thermal oxidation process.

The forming of the SET structure from the FinFET structure may comprise forming a mask layer on the FinFET structure.

The mask layer may cover a gate layer of the FinFET structure, such that respective channel portions on opposite sides of the gate layer remain exposed.

The gate layer of the FinFET structure may function as a part of the mask layer, such that respective channel portions on opposite sides of the gate layer remain exposed.

The mask layer may comprise a hard-mask layer.

The source and drain may remain exposed, and a thickness of the respective channel portions on opposite sides of the gate layer may be chosen such that chemical etching of the respective channel portions occurs before significant removal of material from the source and drain.

The mask layer may be formed such that the source and drain are covered by the mask layer while the respective channel portions remain exposed.

The forming of the active area of the SET structure may comprise a chemical etching process to partially remove material of the channel of the FinFET structure.

The method may comprise forming a plurality of FinFET structures, and forming SET structures from the FinFET structures such that respective active areas of the SET structures are formed from respective channels of the FinFET structures, whereby the active areas are self-aligned with sources and drains of the respective FinFET structures to form the SET structures.

The FinFET structures may comprise single gate or double gate FinFET structures.

Another aspect of the present invention provides an SET fabricated using the method as defined in the first aspect.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1 shows a flowchart illustrating a method for fabrication of SET according to an example embodiment.

FIG. 2A is a top view of a wafer area after FinFET structures are formed according to an example embodiment.

FIG. 2B is a top view of the same area as in FIG. 2A after a mask layer has been deposited according to an example embodiment.

FIG. 2C is a top view of the same area as in FIG. 2A after silicon islands are created and insulator layers are formed according to an example embodiment.

FIG. 3A is a cross-sectional view along line X-X of FIG. 2B according to an example embodiment.

FIG. 3B is a cross-sectional view of the same area as in FIG. 3A after chemical etching according to an example embodiment.

FIG. 3C is a cross-sectional view of the same area as in FIG. 3B after insulator layers are formed according to an example embodiment.

FIG. 4 is a cross-sectional view along line Y-Y of FIG. 2B according to an example embodiment.

FIG. 5 shows a flowchart illustrating a method for fabricating an SET according to an example embodiment.

### DETAILED DESCRIPTION

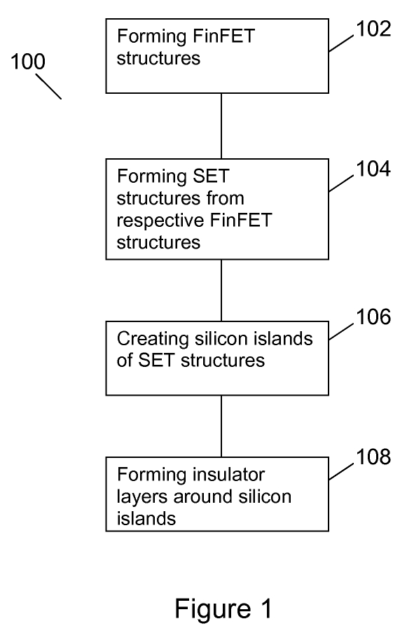

FIG. 1 shows a flowchart, designated generally as reference numeral 100, illustrating a method for the fabrication of SET based on a FinFET manufacturing process according to an example embodiment. At step 102, a plurality of FinFET structures are formed. At step 104, SET structures are formed from respective FinFET structures formed in step 102. At step 106, silicon islands of SET structures are created. At step 108, insulator layers are formed around the silicon islands.

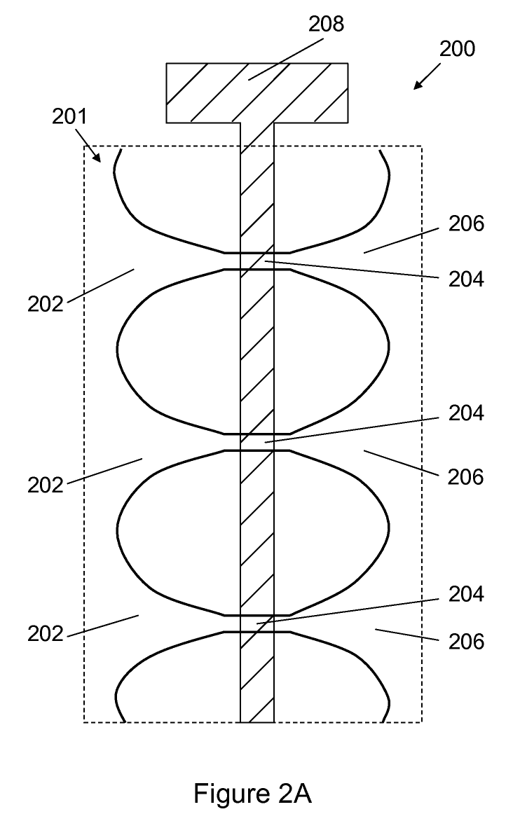

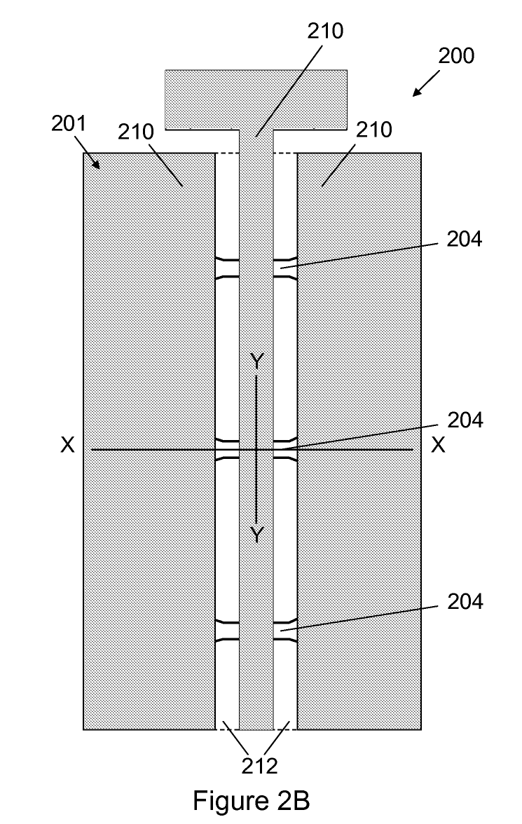

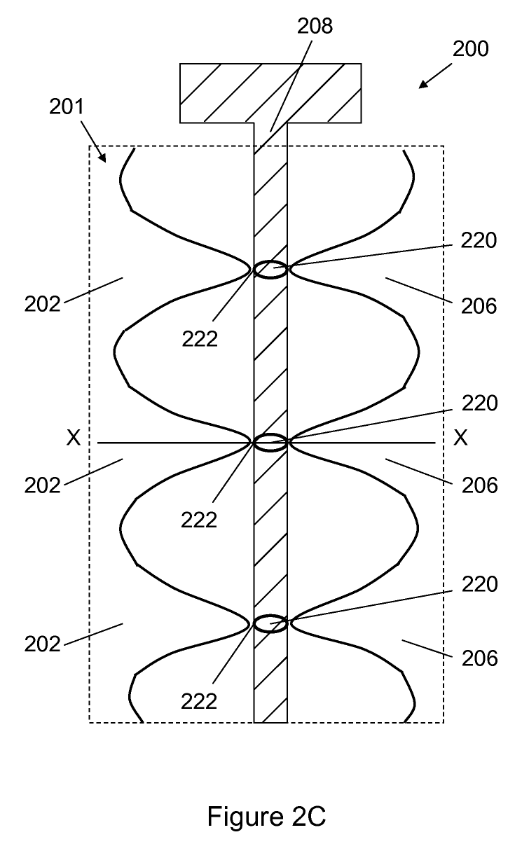

FIG. 2A shows a top view, designated generally as reference numeral 200, of an area 201 on the wafer where a plurality of FinFET structures have been formed from which SET structures are formed, that is, after step 104 (FIG. 1), according to an example embodiment. The process of forming FinFET structures is understood in the art and will not be discussed in detail herein. The structures comprise of a plurality of sources 202, drains 206, gates 208 and channels (or fins) 204, which are thin and straight strips linking the sources 202 and drains 206. The width and thickness of the channels 204 are in the range of tens of nanometers using current technology. The sources 202, channels 204 and drains 206 are normally formed on the wafer, followed by the gates 208, which form a layer around the middle section of the channels 204 and may be of the same or a different semiconductor material from the wafer.

FIG. 2B shows the same area 201 as in FIG. 2A after a mask layer 210 is deposited over portions of the FinFET structures according to an example embodiment. The mask layer 210, illustrated by the shaded regions, is deposited above the sources 202, gate layer 208 and drains 206 after the FinFET structures have been formed such that the sources 202 and drains 206 are covered by the mask layer 210 while portions of the channels 204 of the FinFET structures remain exposed, whereby the mask layer 210 further covers the gate layer 208 but respective channel portions on opposite sides of the gate layer 208 remain exposed. Where the gate layer 208 is formed from a material that is more resistant against chemical etching than the wafer material, the masking of the gate layer 208 is optional because the gate layer 208 functions as a hard mask layer. The mask layer 210 over the sources 202 and drains 206 is also optional where the channel portions on opposite sides of the gate layer 208 (FIG. 2A) are so thin that gaps between the channel portions below the gate layer 208 and respective sources 202 and drains 206 are formed due to chemical etching before significant removal of material from the sources 202 and drains 206. The mask layer 210 may be made of hard-masking materials such as silicon-nitride. The widths of gaps 212 are determined by factors such as channel width, channel thickness, and strength of the etching reagents.

FIG. 2C shows the same area 201 as in FIG. 2A after active areas in the form of silicon islands 220 are created and insulator layers 222 formed around their boundary, that is, after step 108 (FIG. 1), according to an example embodiment. The mask layer 210 (FIG. 2B), if any, is removed after chemical etching is completed. The size of the silicon islands 220 and their separation with respective sources 202 and drains 206 may be controlled by the choice of etching reagent and etching duration. A person skilled in the art would appreciate that the etching process is able to remove silicon material not only vertically but also horizontally through a formulation of the etching reagents. As the silicon islands 220 were originally parts of the channels 204 (FIG. 2A), they are automatically aligned with respective sources 202 and drains 206 after the etching process. Insulator layers 222 may be formed from a thermal oxidation or similar process and their thickness is controlled through process parameters such as time and temperature.

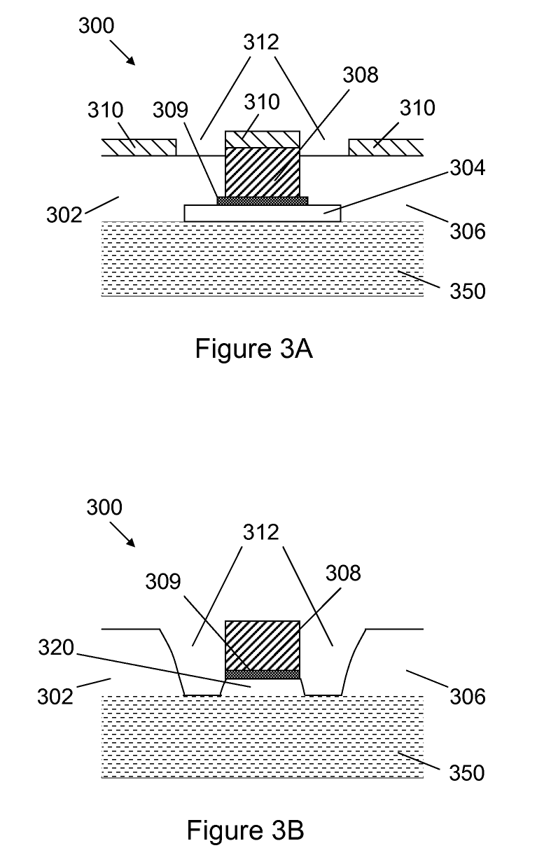

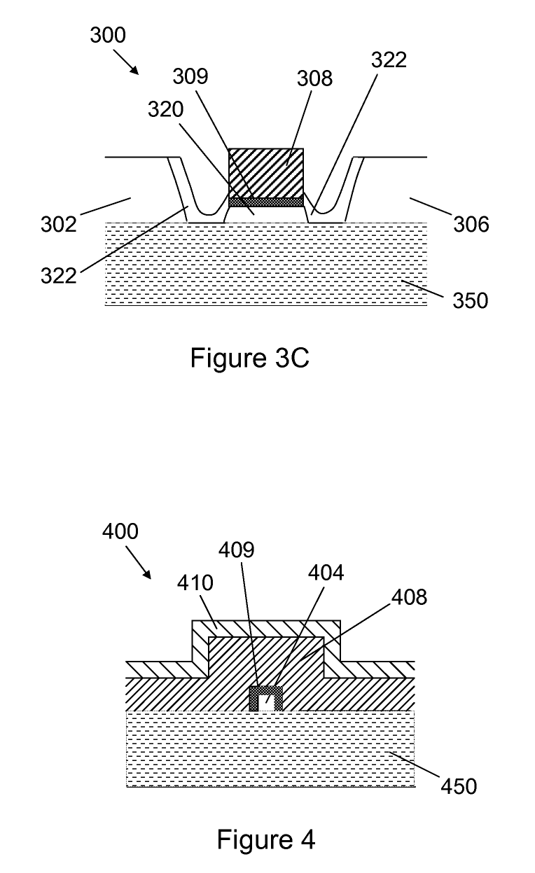

FIG. 3A shows a cross-sectional view, designated generally as numeral 300, along the line X-X of FIG. 2B according to an example embodiment. The wafer substrate 350 may have a different chemical composition; hence, electrical conductivity, from the FinFET components. A thin gate oxide layer 309 is formed around the channel 304 after either the deposition of source 302 and drain 306 material if an epitaxial deposition process is used to obtain raised source 302 and drain 306, or after the source 302, drain 306 and channel 304 are defined on a silicon substrate, such that the gate oxide layer 309 separates the gate layer 308 from the channel 304 after the gate electrode is defined and etched, with or without using side wall spacer formation. The source 302, drain 306 and the gate layer 308 are covered with a mask layer 310 such that respective channel portions on opposite sides of the gate layer 308 remain exposed. The unmasked gaps 312 are the locations where the etching reagents act to remove the silicon and their widths can be optimized as discussed. Where the gate material is resistant against chemical etching, the mask layer 310 on top of the gate layer 308 is optional because the gate layer 308 functions as a hard mask layer. The mask layer 310 over the source 302 and drain 306 is also optional where the channel portions on opposite sides of the gate layer 308 are so thin that gaps between the channel portion below the gate layer 308 and respective source 302 and drain 306 are formed due to chemical etching before significant removal of material from the source 302 and drain 306.

FIG. 3B shows a cross-sectional view of the same area as in FIG. 3A after chemical etching according to an example embodiment. The mask layer 310 (FIG. 3A) is removed after chemical etching is completed. The material in exposed gaps 312 is removed by the etching reagents such that the depth of gaps 312 is controlled by process parameters including the etching duration and type of reagents. It is preferable that the etching reagents remove not only the part of silicon material of the source 302 and drain 306 but also the material of the gate oxide layer 309 and channel 304 until a silicon island 320 is formed and completely separated from its respective source 302 and drain 306, and such that the depth of gaps 312 extends up to the substrate layer 350. It is also preferable that the widths of gaps 312 are controlled such that complete separation is achieved at the bottom of the gaps 312 even as the side surfaces of silicon island 320, source 302 and drain 306 are inwardly gradient, which could be adjusted with proper formulation of the etching reagents.

FIG. 3C shows a cross-sectional view of the same area as in FIG. 3B after insulator layers 322 are formed according to an example embodiment. As the unmasked silicon in the gaps 312 (FIG. 3A) is removed, the remaining silicon forms the SET structure in which the silicon island 320 is separated from respective source 302 and drain 306. The amount of separation, which ranges from 1 nm to 10 nm, may determine the ease of electron tunnelling (or Coulomb blockade effect), hence the efficiency of the SET. The amount of separation is controlled by process parameters such as gap widths and etching duration. An insulator layer 322 is formed from a thermal oxidation or similar process such that the oxide covers the side surfaces of the silicon island 220 facing the source 302 and drain 306, as well as the corresponding side surfaces of source 302 and drain 306. The oxide further forms a layer at the bottom of gaps 312 (FIG. 3B) such that the bottom of the oxide layer is at the interface with the substrate layer 350 and the top of the oxide converge with the oxide similarly formed on the side surfaces of the island 320, source 302 and drain 306. The thickness of the insulator layer 322 may also control the Coulomb blockade effect. The substrate 350 could be of a material very different from silicon, e.g. silicon oxide, in which case the thermal oxidation process will not form further oxide on its surface. It is expected that the gap would still be filled when the oxide grows, as the volume of oxide is larger than the volume of the silicon consumed for oxidation. However, in one variant example embodiment, the resulting device structure can have small gap remaining. In another variant example embodiment, such a gap may be filled with another oxide material, for e.g. High K material.

FIG. 4 shows a cross-sectional view, designated generally as numeral 400, along the line Y-Y of FIG. 2B according to an example embodiment. The cross section along the line Y-Y is not changed from this point onward in the fabrication of the SET except for the removal of the mask layer 410 after chemical etching is complete. A channel 404 is vertically protruding from the wafer substrate 450 (hence it is called ‘fin’). The height and width of the channel 404 is in the range of tens of nanometers. A gate oxide layer 409 is formed such that no part of the gate layer 408 is in direct contact with the channel 404. The gate layer 408 covers not only the space between consecutive channels 404 but also over the top surface of each channel 404 (compare top view in FIG. 2A). The thickness of the gate layer 408 is controlled depending on the channel thickness. The mask layer 410 is deposited above the gate layer 408 after the FinFET structures are formed. Where the gate material is resistant against chemical etching, the mask layer 410 is optional after the FinFET structures are formed, as the gate layer 408 can acts as a hard mask layer.

The example embodiments described can provide a technique for fabrication of SET based on the FinFET manufacturing method to achieve self-organized and aligned islands, giving the devices thus fabricated uniform performance. It will be appreciated that, because the active areas of the SETs are very small, the separation and alignment of the islands with respective sources and drains are critical for achieving the Coulomb blockade effect in which the movement of a single or a few electrons causes measurable voltage change compared to electron thermal energy.

The technique as described in the example embodiments may start with the formation of bulk silicon or silicon-on-insulator (SOI) wafer. Typically, for an SOI wafer, the oxide thickness is in the region of 400 nm and the silicon thickness is in the region of 50 nm. An alternative semiconductor material such as Germanium may be used as a substitute for silicon. The channel (fin), source and drain are patterned by a combination of lithography, for example, electron beam lithography, Deep Ultra-Violet (DUV) lithography, I-line lithography, or a similar kind of scanner, and chemical etching. It will be appreciated that for SETs, the doping of the source and drain is not very critical. However, if doping is desired, e.g. for device optimization, the doping can be done on the starting material itself, or the doping can be done after the gate has been defined in variant example embodiments.

Alternatively, the channel (fin) is patterned first, and then doped amorphous silicon is deposited to serve as source and drain and also to achieve the raised source and drain. A gap is formed between the created source and drain, either as part of the patterning of the source and drain, or through an additional step of removal of the doped amorphous silicon in the middle section above the channel. Spacers may be optionally formed on side surfaces of the etched gap. Subsequently, a gate layer is formed over and in the gap at the middle section above the channel. The gate layer may be formed from high-k dielectric material with or without metal gates to enhance performance.

Following from this conventional-like FinFET formation, in the example embodiments, the completed FinFET structures then undergo chemical etching to remove portions of the FinFET structures on either side of the gate layer, for forming small islands, which are readily aligned with respective sources and drains. The boundary of the islands is oxidised to form insulator layers between the islands and respective sources and drains. The structures thus formed can now observe Coulomb blockade effect for the tunnelling of electrons, which is controlled through the separations between the islands and the respective sources and drains, and the thickness of the oxide layer.

The example embodiments described may advantageously provide a method to fabricate islands of SET structures in an order of less than about 10 to 15 nanometers, which are critical for SET to function. In addition, the islands fabricated may be self-aligned and symmetric and may result in better drive current and performance. The example embodiments described may also be applied on a production scale at a relatively lower cost than existing methods. It is potentially possible to use the method described in the example embodiments on any future three or four terminal devices, or to realize atomic or molecular-level devices.

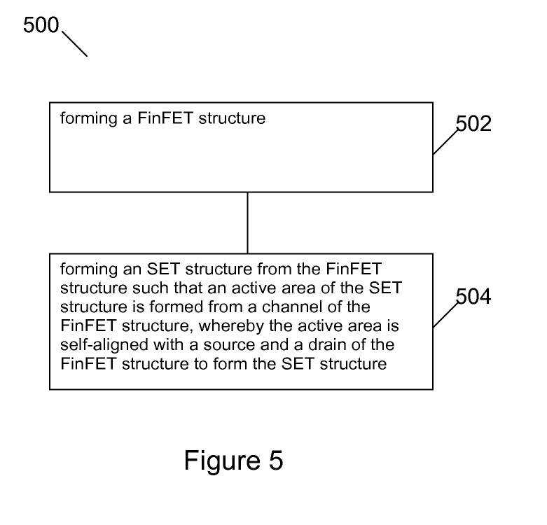

FIG. 5 shows a flowchart 500 illustrating a method for fabricating an SET according to an example embodiment. At step 502, a FinFET structure is formed. At step 504, an SET structure is formed from the FinFET structure such that an active area of the SET structure is formed from a channel of the FinFET structure, whereby the active area is self-aligned with a source and a drain of the FinFET structure to form the SET structure.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

1. A method for fabricating a Single Electron Transistor (SET), the method comprising:
forming a FinFET structure,
forming an SET structure from the FinFET structure such that an active area of the SET structure is formed from a channel of the FinFET structure, whereby the active area is self-aligned with a source and a drain of the FinFET structure to form the SET structure.

2. The method as claimed in claim 1, further comprising forming an insulator layer around the active area.

3. The method as claimed in claim 2, wherein the forming of the insulator layer comprises a thermal oxidation process.

4. The method as claimed claim 1, wherein the forming of the SET structure from the FinFET structure comprises forming a mask layer on the FinFET structure.

5. The method as claimed in claim 4, wherein the mask layer covers a gate layer of the FinFET structure, such that respective channel portions on opposite sides of the gate layer remain exposed.

6. The method as claimed in claim 4, wherein a gate layer of the FinFET structure functions as part of the mask layer, such that respective channel portions on opposite sides of the gate layer remain exposed.

7. The method as claimed claim 4, wherein the mask layer comprises a hard-mask layer.

8. The method as claimed in claim 5, wherein the source and drain remain exposed, and a thickness of the respective channel portions on opposite sides of the gate layer is chosen such that chemical etching of the respective channel portions occurs before significant removal of material from the source and drain.

9. The method as claimed in claim 5, wherein the mask layer is formed such that the source and drain are covered by the mask layer while the respective channel portions remain exposed.

10. The method as claimed in claim 4, wherein the forming of the active area of the SET structure comprises a chemical etching process to partially remove material of the channel of the FinFET structure.

11. The method as claimed in claim 1, comprising:
forming a plurality of FinFET structures,
forming SET structures from the FinFET structures such that respective active areas of the SET structures are formed from respective channels of the FinFET structures, whereby the active areas are self-aligned with sources and drains of the respective FinFET structures to form the SET structures.

12. The method as claimed in claim 1, wherein the FinFET structures comprise single gate or double gate FinFET structures.

13. A SET fabricated using the method as claimed in claim 1.
